(19) United States
(12) Patent Application Publication
(10) Pub. No.: US 2006/0030083 A1
(43) Pub. Date: Feb. 9, 2006

(54) Semiconductor device and fabricating method thereof

(76) Inventor: Bing-Chang Wu, Hsinchu County (TW)

Correspondence Address: J.C. Patents, Suite 250, 4 Venture, Irvine, CA, 92618, US

(21) Appl. No.: 11/250,826

(22) Filed: Oct. 13, 2005

Related U.S. Application Data
(62) Division of application No. 10/839,522, filed on May 4, 2004.

(51) Int. Cl. H01L 21/82

(52) U.S. Cl. 438/132

(57) ABSTRACT

A semiconductor device comprising a substrate with an integrated circuit structure and a patterned metallic layer thereon is provided. The patterned metallic layer includes a first pattern and a second pattern. The first pattern has a thickness different from the second pattern. Since the first pattern and the second pattern on the substrate each has a thickness optimized for their respective use, performance of the semiconductor device is improved.

### BACKGROUND OF THE INVENTION

1. Field of the Invention

The present invention relates to a semiconductor device and fabricating method thereof. More particularly, the present invention relates to a semiconductor device having an optimized bonding pad and fuse thickness and fabricating method thereof.

2. Description of the Related Art

At present, most semiconductor devices are fabricated on silicon wafers. To increase production yield and lower production cost, the diameter of wafers has been increased from 4, 5 or 6 inches to 8 inches and more. Furthermore, the miniaturization of integrated circuit devices on the wafer continues so that more chips can be fabricated on the same piece of silicon wafer.

Most integrated circuit chips have a number of bonding pads for connecting with an external circuit. Due to possible damage to any film layer underneath the bonding pads when there is a mismatch in parameters during the wire-bonding or other bonding operations, integrated circuits are not formed underneath the bonding pads. However, as size of the integrated circuits continues to decrease, the convention method of positioning the bonding pads often leads to a reduction in the number of integrated circuits on a single chip. Thus, to reduce waste and increase spatial utilization, bonding pads are currently formed over the integrated circuits as well.

To prevent any damage to the underlying integrated circuits due to excessive stress on the bonding pad during a wire-bonding or other bonding operations, thickness of the bonding pad is critical. In other words, the bonding pad must have a sufficient thickness to withstand the stress created during a wire-bonding operation or some other bonding processes.

In general, to be cost effective, the bonding pads and the fuse for repairing circuits are fabricated in the same processing operation. In other words, the bonding pads and the fuses are formed after patterning the same film layer. Consequently, the bonding pads and the fuse will have an identical thickness. However, the fuses are used for controlling the conductivity of the repair circuit. Hence, the fuses must be sufficiently thin to let a laser beam pass through and cut a fuse in a repair operation.

Although the bonding pads and the fuses are formed on the same film layer, thickness of the bonding pads and the fuses ought to be separately optimized. Conventionally, the film layer is chosen to have a thickness between the threshold value of a bonding pad and the threshold value of a fuse. In this way, however, neither the bonding pad nor the fuse is optimized.

### SUMMARY OF THE INVENTION

Accordingly, the present invention is directed to a semiconductor device having devices of optimized thickness so that the best performance is obtained.

The present invention is also directed to a method of fabricating a semiconductor device capable of forming patterns with different thickness out of a metallic layer to serve different devices so that the performance of these devices are optimized.
according to an embodiment of the present invention, the semiconductor device mainly comprises a substrate with an integrated circuit structure and a patterned metallic layer formed thereon. The patterned metallic layer includes a first pattern and a second pattern. The first pattern has a thickness different from the second pattern.

According to an embodiment of the present invention, the first pattern and the second pattern of the patterned metallic layer are the bonding pads and the fuses of the semiconductor device. Furthermore, the bonding pads have a thickness greater than the fuses.

The present invention also directed to a method of fabricating a semiconductor device. First, a substrate with an integrated circuit structure formed thereon is provided. Thereafter, a patterned metallic layer is formed over the integrated circuit structure. The patterned metallic layer includes patterns each having a different thickness.

According to an embodiment of the present invention, the patterns in the patterned metallic layer includes the bonding pad structures and the fuse structures in the semiconductor devices. Furthermore, the bonding pads have a thickness greater than the fuses.

According to an embodiment of the present invention, the thickness of each pattern in the patterned metallic layer can be optimized to serve a particular purpose. Hence, all the semiconductor devices can perform in their respective optimal states.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the steps for fabricating a semiconductor device according to a preferred embodiment of the present invention.

FIGS. 2A and 2B are schematic cross-sectional views showing the steps of fabricating a semiconductor device according to an embodiment of the present invention.

FIG. 3 is a top view of the semiconductor device in FIG. 1D.

FIG. 4 is a schematic cross-sectional view of a semiconductor device according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

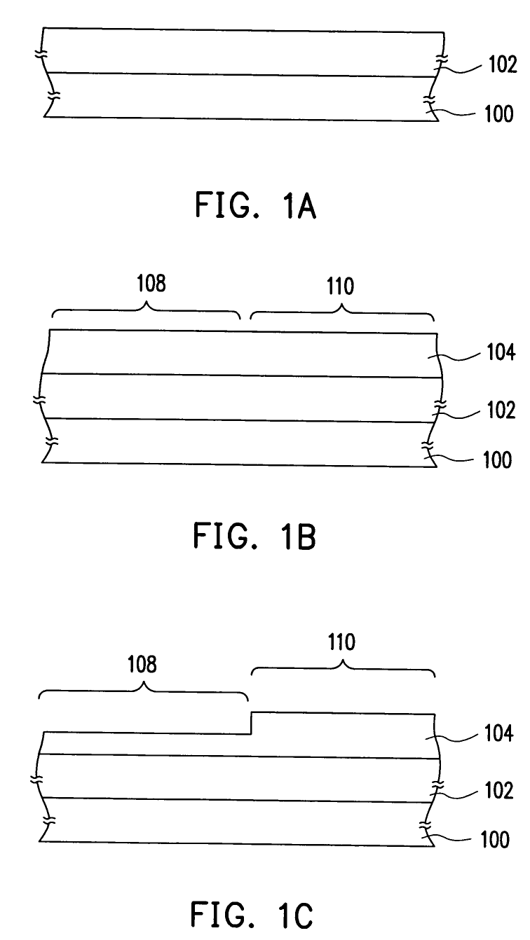

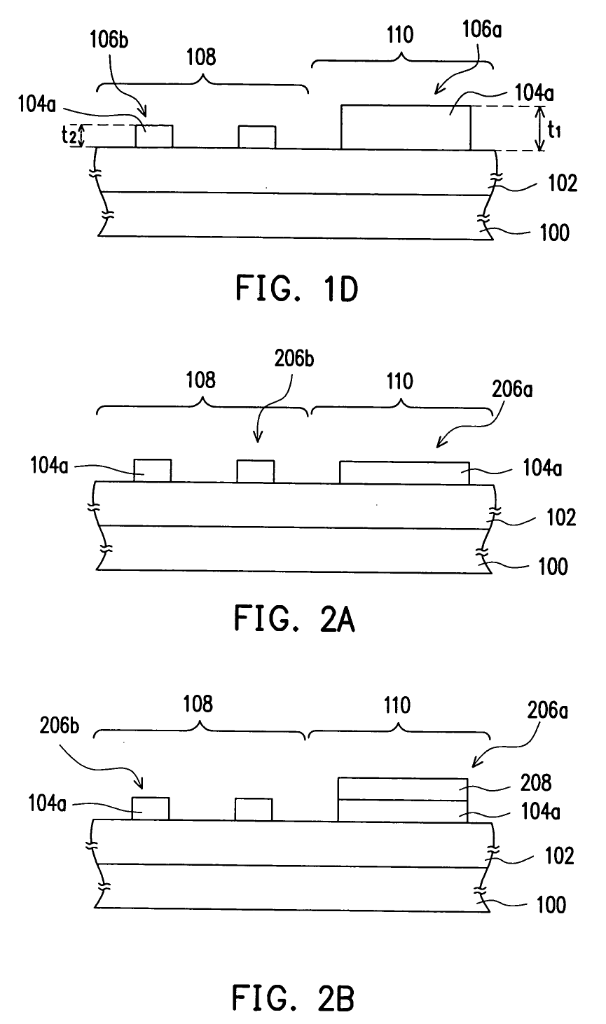

FIGS. 1A through 1D are schematic cross-sectional views showing the steps of fabricating a semiconductor device according to an embodiment of the present invention. A semiconductor substrate 100 having an integrated circuit structure 102 formed thereon is provided. To simplify the figure in FIG. 1A, the devices in the integrated circuit structure 102 are not shown in the drawings. In general, the integrated circuit structure 102 comprises a plurality of circuit elements and metallic interconnects.

As shown in FIG. 11B, a metallic layer 104 is formed over the integrated circuit structure 102. The metallic layer is an aluminum layer divided into a first region 108 and a second region 110, for example.

As shown in FIG. 1C, the metallic layer 104 within the first region 108 is trimmed down so that the metallic layer 104 within the first region 108 has a smaller thickness than the metallic layer 104 within the second region 110. To reduce the thickness of the metallic layer 104 within the first region 108, a photoresist layer (not shown) is formed over the metallic layer 104 within the second region 110. Thereafter, the first metallic layer 104 within the first region 108 is etched using the photoresist layer as an etching mask, for example. Finally, the photoresist layer is removed.

As shown in FIG. 1D, the metallic layer 104 is patterned to form a metallic layer 104a having a first pattern 106a within the second region 110 and a second pattern 106b within the first region 108. The patterned metallic layer 104a is formed, for example, by performing a photolithographic process followed by an etching process.

In the aforementioned process, the first pattern 106a has a thickness greater than the second pattern 106b. In an embodiment, the first pattern 106a is a bonding pad structure in a semiconductor device, for example. Hence, the first pattern 106a has a thickness between 0.8 μm to 1.6 μm and preferably a thickness of about 1.2 μm. On the other hand, the second pattern 106b is a fuse structure in a semiconductor device, for example. Hence, the second pattern 106b preferably has a thickness smaller than 0.8 μm.

It should be noted that an alternative process could also be used to form a pattern of different thickness in the metallic layer 104 as described according to another embodiment of the present invention. Hence, the scope of the present invention includes any method of forming patterns in a metallic layer such that each pattern has a different thickness.

FIGS. 2A and 2B are schematic cross-sectional views show the steps of fabricating a semiconductor device according to the present invention. As shown in FIG. 2A, according to the aforementioned embodiment in FIGS. 1A and 1B, after forming the metallic layer 104 over the integrated circuit structure 102, the metallic layer 104 is patterned to form the metallic layer 104a. Furthermore, the patterned metallic layer 104a comprises the first pattern 206a and the second pattern 206b. The metallic layer 104 is patterned, for example, by performing a photolithographic and etching process, for example.

As shown in FIG. 2B, another metallic layer 208 is formed over the first pattern 206a so that the first pattern 206a has a greater thickness than the second pattern 206b. Similarly, as in the aforementioned embodiment, the first pattern 106a is a bonding pad structure in a semiconductor device and the second pattern 106b is a fuse structure in a semiconductor device, for example. Since considerations such as thickness are almost identical to the aforementioned embodiment, detailed description thereof is therefore omitted hereinafter.

Because the main difference between the structure shown in FIG. 1D and the one shown in FIG. 2B is in the number of layers constituting the first pattern, the fabrication is described in the following with reference to FIG. 1D only. It should be understood that the same process is applicable for fabricating the semiconductor devices in FIG. 2B as well. In addition, since the material constituting the device and the method of fabrication has already been described in the aforementioned embodiment, and therefore detail description thereof are not repeated hereinafter.

As shown in FIG. 1D, the semiconductor device mainly comprises a substrate 100 with an integrated circuit structure 102 and a patterned metallic layer 104a. The patterned metallic layer 104a further comprises a first pattern 106a and a second pattern 106b. The first pattern 106a has a thickness t₁ and the second pattern 106b has a thickness t₂ such that t₁ is greater than t₂.

In particular, according to one embodiment of the present invention, the first pattern 106a has a thickness t₁ between 0.8μ to 1.6 μm and preferably about 1.2 μm while the second pattern 106b has a thickness t₂ smaller than 0.8 μm.

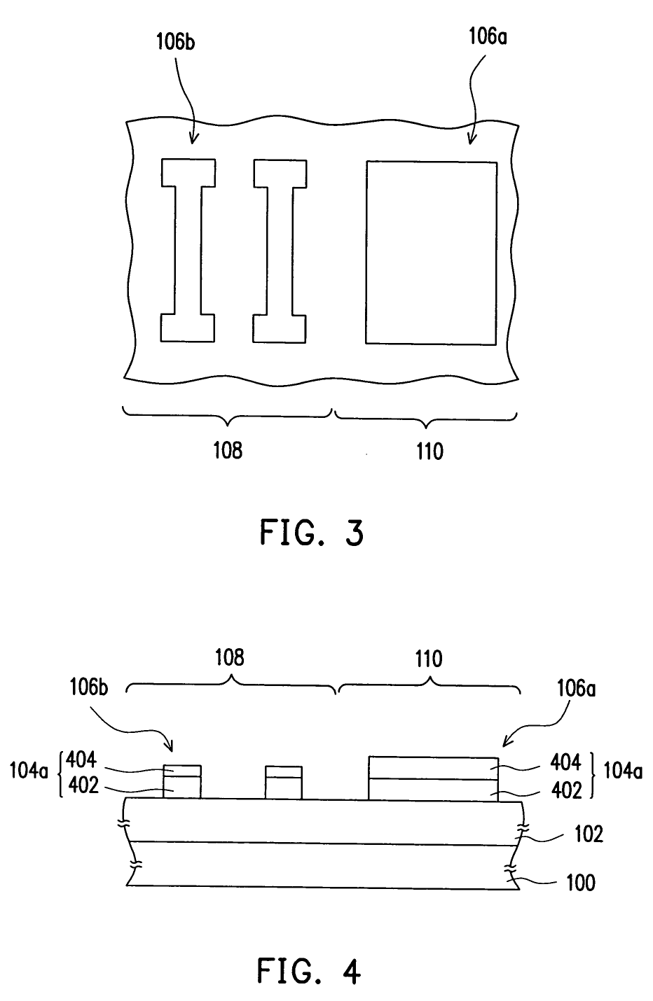

FIG. 3 is a top view of the semiconductor device in FIG. 1D. As shown in FIG. 3, the first pattern 106a is a bonding pad structure in a semiconductor device and the second pattern 106b is a fuse structure in a semiconductor device, for example.

In addition, the metallic layer 104 in FIG. 1B can be a composite metallic layer according to another embodiment of the present invention. FIG. 4 is a schematic cross-sectional view of a semiconductor device according to another embodiment of the present invention. The patterned metallic layer 104a in FIG. 4 comprises a first metallic layer 402 as well as a second metallic layer 404 formed over the first metallic layer 402. Although two metallic layers are used to form the patterned metallic layer 104a, the number of metallic layers forming the patterned metallic layer 104a may be determined by actual need.

Accordingly, the present invention permits the formation of a multitude of patterns each having a different thickness on the same film layer so that each pattern can have a thickness optimized for a particular function. For example, thick bonding pads and thin fuses can be fabricated on the semiconductor devices at the same time. Thus, the integrated circuit beneath the bonding pads is prevent from any damage after a wire-bonding or other bonding processes and fuses is easily cut by a laser beam in a circuit repair operation.

It should be noted that the bonding pad is subjected to a smaller stress during a wire-bonding operation because the bonding pad on the semiconductor device has a greater thickness. According to experiments on 0.13 μm and 0.09 μm line width processes, a bonding pad with a thickness of about 1.2 μm has a 75% reduction in compressive stress and 50% reduction in shear stress compared with a conventional bonding pad with a thickness of about 0.8 μm. Therefore, the bonding pads on the semiconductor devices according to the present invention are tougher. In other words, the present invention increases the thickness of the bonding pads on the semiconductor devices with to protect the underlying integrated circuit structures but reduces the thickness of fuse structures to facilitate circuit repair using a laser beam.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1-7. (canceled)

8. A method of fabricating a semiconductor device, comprising the steps of:
providing a semiconductor substrate having an integrated circuit structure formed thereon; and
forming a patterned metallic layer over the integrated circuit structure such that the pattern metallic layer comprises patterns each having a different thickness.

9. The method of claim 8, wherein the step of forming the patterned metallic layer comprises:
forming a metallic layer over the integrated circuit structure; and
patterning the metallic layer to form a first pattern and a second pattern, wherein the first patter has a thickness different from the second pattern.

10. The method of claim 9, wherein the step of patterning the metallic layer to form the first pattern and the second pattern comprises:
reducing the thickness of the metallic layer in one particular area, wherein the area is designated for forming the first pattern; and
etching the metallic layer to form the first pattern in the area and the second pattern in the remaining metallic layer covered area.

11. (canceled)

12. The method of claim 8, wherein the patterned metallic layer comprises a bonding pad structure and a fuse structure such that the bonding pad structure has a thickness greater than the fuse structure.

13. The method of claim 12, wherein the bonding pad has a thickness between about 0.8 μm to 1.61 μm.

14. The method of claim 12, wherein the fuse has a thickness smaller than 0.8 μm.
